(19) United States
(12) Patent Application Publication
(10) Pub. No.: US 2024/0361389 A1
(43) Pub. Date: Oct. 31, 2024

(54) BATTERY MODULE MONITORING CIRCUIT INCLUDING REMOTE WIRELESS TRANSCEIVER

(71) Applicant: Gentherm GmbH, Odelzhausen (DE)

(72) Inventors: Jason CHANG, Northville, MI (US); Saifedine BOUAJIA, Augsburg (DE)

(21) Appl. No.: 18/308,741

(22) Filed: Apr. 28, 2023

(51) Int. Cl. G01R 31/371; H01M 10/48

(52) U.S. Cl. CPC G01R 31/371; H01M 10/482; H01M 2010/4278

(57) ABSTRACT

A wireless battery module monitoring system includes a flexible printed circuit (FPC) including a first insulating layer. A conductive layer defines a plurality of traces arranged in a first predetermined pattern. A battery module monitoring circuit is connected to at least one of the plurality of traces of the FPC. A wireless transceiver is connected to at least one of the plurality of traces of the FPC at a location remote from the battery module monitoring circuit. An antenna is one of mounted on the FPC and connected to the wireless transceiver and implemented by at least one of the plurality traces of the conductive layer of the FPC and connected to the wireless transceiver.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates to a battery module monitoring circuit for a battery module, and more particularly to a battery module monitoring circuit including a remote wireless transceiver.

Electric vehicles such as battery electric vehicles and hybrid vehicles are powered by a battery pack including one or more battery modules each including one or more battery cells. A battery monitoring system (BMS) wirelessly communicates with a plurality of battery module monitoring circuits arranged in each of the module enclosures to sense battery module operating parameters such as voltage, current, temperature, impedance and/or other parameters and/or to receive commands, data, and/or programming. The battery module monitoring circuits include various other circuits for monitoring the battery module parameters and a wireless transceiver circuit and antenna to transmit and receive information to/from a wireless transceiver of the BMS.

### SUMMARY

A wireless battery module monitoring system includes a flexible printed circuit (FPC) including a first insulating layer. A conductive layer defines a plurality of traces arranged in a first predetermined pattern. A battery module monitoring circuit is connected to at least one of the plurality of traces of the FPC. A wireless transceiver is connected to at least one of the plurality of traces of the FPC at a location remote from the battery module monitoring circuit. An antenna is one of mounted on the FPC and connected to the wireless transceiver and implemented by at least one of the plurality traces of the conductive layer of the FPC and connected to the wireless transceiver.

In other features, the plurality of traces of the FPC are milled. The FPC includes a second insulating layer. The conductive layer is arranged between the first insulating layer and the second insulating layer. A measuring circuit is arranged on the FPC, connected to at least one of the plurality of traces and to the battery module monitoring circuit, and configured to measure at least one of module voltage, cell voltage, cell temperature and impedance.

In other features, at least one of the plurality of traces of the conducting layer is connected at least one of a module busbar, a cell busbar, and a cell temperature sensor.

A battery module comprises a battery enclosure including a plurality of battery cells, a frame, and the wireless battery module monitoring system arranged on the frame in the battery enclosure.

A wireless battery module monitoring system includes a first printed circuit board (PCB) and a battery module monitoring circuit arranged on the first PCB. A first flexible printed circuit (FPC) includes a first insulating layer and a first conductive layer defining a plurality of first traces arranged in a first predetermined pattern. A wireless transceiver is arranged on the first FPC at a location remote from the first PCB, and connected to at least one of the plurality of first traces. An antenna is one of mounted on the first FPC and connected to the wireless transceiver and implemented by at least one of the plurality of first traces and connected to the wireless transceiver.

In other features, the plurality of first traces of the first FPC are milled. The first FPC further comprises a second insulating layer. The first conducting layer is arranged between the first insulating layer and the second insulating layer. The first PCB is arranged adjacent to an edge of the first FPC and at least one of the plurality of first traces is connected to at least one pad on the first PCB. The first PCB is mounted above the first FPC and is soldered to at least one of the plurality of first traces.

In other features, a measuring circuit is arranged on the first PCB, connected by at least one of the plurality of traces of the first FPC to the battery module monitoring circuit, and configured to measure at least one of module voltage, cell voltage, cell temperature and impedance.

In other features, a second FPC including a second insulating layer and second conducting layer defining a plurality of second traces arranged in a second predetermined pattern. At least one of the plurality of second traces defines a resistor connected to at least one pad of the first PCB. At least one of the plurality of second traces of the second conducting layer connects at least one of a module busbar, a cell busbar, and a cell temperature sensor to one or more pads of the first PCB. The plurality of second traces of the second FPC are milled. The wireless transceiver is mounted on a second PCB attached to the first FPC.

A battery module includes a plurality of battery cells, a frame, and a battery enclosure. The wireless battery module monitoring system is arranged on the frame in the battery enclosure.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 is a functional block diagram of an example of a battery pack including a battery management system and a plurality of battery modules including battery module monitoring circuits including wireless transceivers;

FIG. 2 is a functional block diagram of an example of a battery pack including a battery management system and a plurality of battery modules including battery module monitoring circuits with wireless transceivers arranged remotely from the battery module monitoring circuits according to the present disclosure;

FIG. 3A is a functional block diagram of an example of a battery module monitoring circuit arranged on a PCB and a wireless transceiver arranged on a flexible printed circuit (FPC) remotely from the battery module monitoring circuit according to the present disclosure;

FIG. 3B is a side cross sectional view of an example of a FPC according to the present disclosure;

FIG. 4A is a functional block diagram of an example of a battery module monitoring circuit arranged on a PCB mounted on a FPC and a wireless transceiver arranged on the FPC remotely from the PCB according to the present disclosure;

FIG. 4B is a functional block diagram of an example of a battery module monitoring circuit including a first PCB mounted on a FPC and a wireless transceiver including a second PCB arranged on the FPC remotely from the PCB according to the present disclosure;

FIG. 5A is a functional block diagram of an example of a battery module monitoring circuit attached to a FPC and a wireless transceiver attached to the FPC remotely from the battery module monitoring circuit according to the present disclosure;

FIG. 5B is a side cross sectional view of an example of a flexible printed circuit including multiple conductor layers according to the present disclosure;

FIG. 6 is a perspective view of an example of a battery module monitoring circuit and a remote wireless transceiver arranged in a battery module enclosure.

In the drawings, reference numbers may be reused to identify similar and/or identical elements.

### DETAILED DESCRIPTION

A battery monitoring system for a plurality of battery modules each including a battery module monitoring circuit and a wireless transceiver and antenna arranged inside of the enclosures of the battery modules. The battery module monitoring circuit and the wireless transceiver include integrated circuits or chips or other circuits that are typically mounted on the same printed circuit board (PCB). Traces on the PCB provide connections between circuits on the PCB. External connections to the PCB are made using pads and traces on the PCB.

The wireless transceiver of the battery module monitoring circuit needs to be independently tested and certified (or homologated) prior to sale of the battery module monitoring circuit. Because the wireless transceiver is arranged on the same PCB as the battery module monitoring circuit, the independent testing and certification needs to occur each time that a major component of the battery module monitoring circuit is changed, which increases development and validation costs.

Since the battery module monitoring circuit, the wireless transceiver, and the antenna are typically located on the same PCB, placement of the PCB in the enclosure is driven by the need for effective wireless communication. However, the best location for the wireless transceiver and the antenna may not be the best location for the rest of the battery module monitoring circuit.

A battery monitoring system according to the present disclosure includes a battery module monitoring circuit that is located in the battery module enclosure remotely and a wireless transceiver and antenna. The separation of the battery module monitoring circuit from the wireless transceiver and the antenna allows increased packaging flexibility. In other words, the battery module monitoring circuit can be packaged in its optimal position in the battery module enclosure and the wireless transceiver and the antenna can be packaged in the battery module enclosure to optimize wireless communication. Alternately, the battery module monitoring circuit can be packaged in its optimal position in the battery module enclosure and the wireless transceiver and the antenna can be packaged outside of the battery module enclosure to optimize wireless communication. In addition, when changes are made to the battery module monitoring circuit, independent testing and certification of the wireless transceiver and the antenna is no longer required since they are no longer co-located on the same PCB.

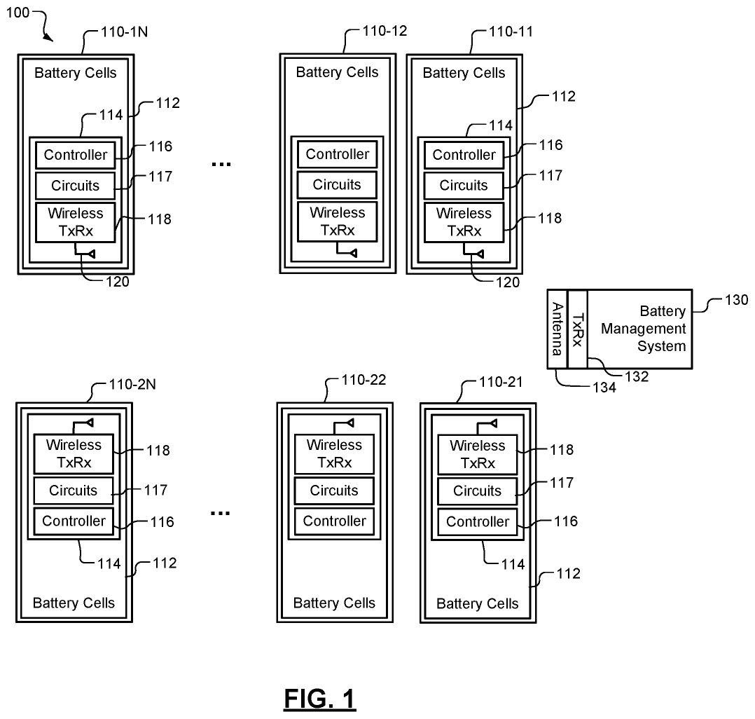

Referring now to FIG. 1, a battery pack 100 includes a plurality of battery modules 110-11, 110-12, . . . , 110-1N, 110-21, 110-22, . . . , and 110-2N, where N is an integer greater than one (collectively or individually referred to as battery module(s) 110). Each of the battery modules 110 includes a plurality of battery cells (not shown) and a battery module monitoring circuit 114 including a controller 116, other circuits 117 such as temperature, voltage or current measuring circuits, a wireless transceiver (TxRx) 118, and an antenna 120. The controller 116, the other circuits 117, the wireless transceiver 118, and the antenna 120 of the battery module monitoring circuit 114 are arranged on the same PCB.

A battery management system 130 includes a controller and other circuits (not shown) that are configured to communicate with and/or control the battery pack 100 and/or to communicate with a propulsion controller of an electric vehicle 112. The battery management system 130 also includes a wireless transceiver 132 and an antenna 134 that communicate with the wireless transceivers 118 of each of the battery modules 110.

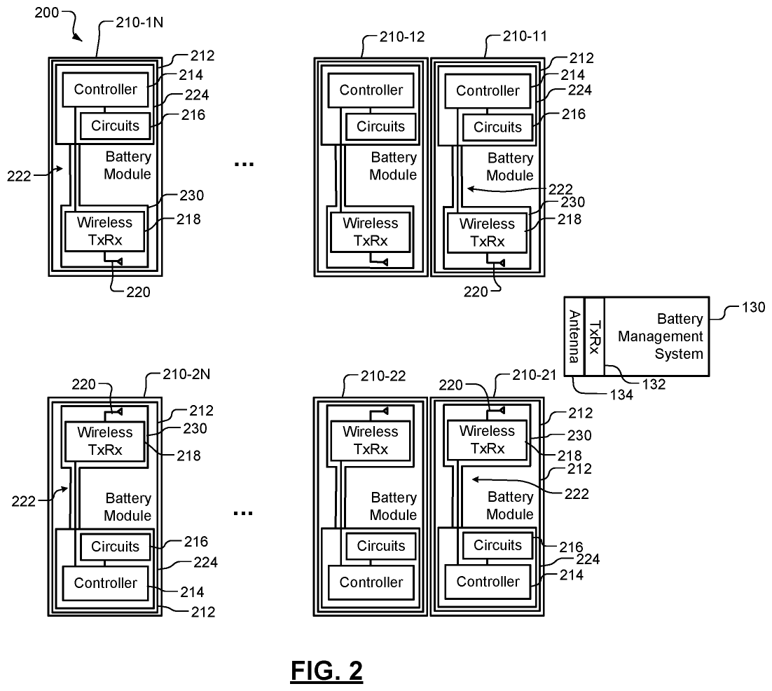

Referring now to FIG. 2, a battery pack 200 according to the present disclosure includes a plurality of battery modules 210-11, 210-12, . . . , 210-1N, 210-21, 210-22, . . . , and 210-2N, where N is an integer greater than one (collectively or individually referred to as battery module(s) 210). Each of the battery modules 210 includes a plurality of battery cells 212 and a battery module monitoring circuit including a controller 214, other circuits 216 (e.g., temperature, voltage or current measuring circuits), a wireless transceiver (TxRx) 218, and/or an antenna 220.

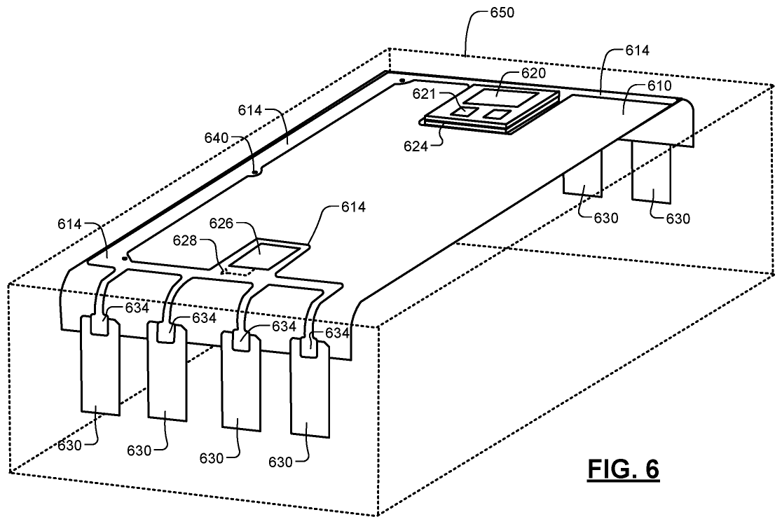

The battery module monitoring circuit (e.g., the controller 214 and other circuits 216), the wireless transceiver 218, and the antenna 220 are arranged within a battery module enclosure (FIG. 6). The controller 214 and other circuits 216 are located independently of (e.g., remote from) the wireless transceiver 218 and the antenna 220. In other words, the battery module monitoring circuit (e.g., the controller 214 and other circuits 216) and the wireless transceiver 218 (and the antenna 220) are not located on the same PCB, which allows placement in optimized locations for each. A system bus 222 supplies signals such as power, ground and/or data between the controller 214 and other circuits 216 and the wireless transceiver 218. In some examples, the wireless transceiver 218 comprises an integrated circuit.

As will be described further below, the controller 214 and other circuits 216 are mounted on a substrate 224. In some examples, the substrate 224 is selected from a group consisting of a printed circuit board (PCB), a PCB mounted on a flexible printed circuit (FPC), or a FPC. The wireless transceiver 218 and/or the antenna are mounted on a substrate 230 such as a first printed circuit board (PCB), a first PCB mounted on a flexible printed circuit (FPC), or the FPC.

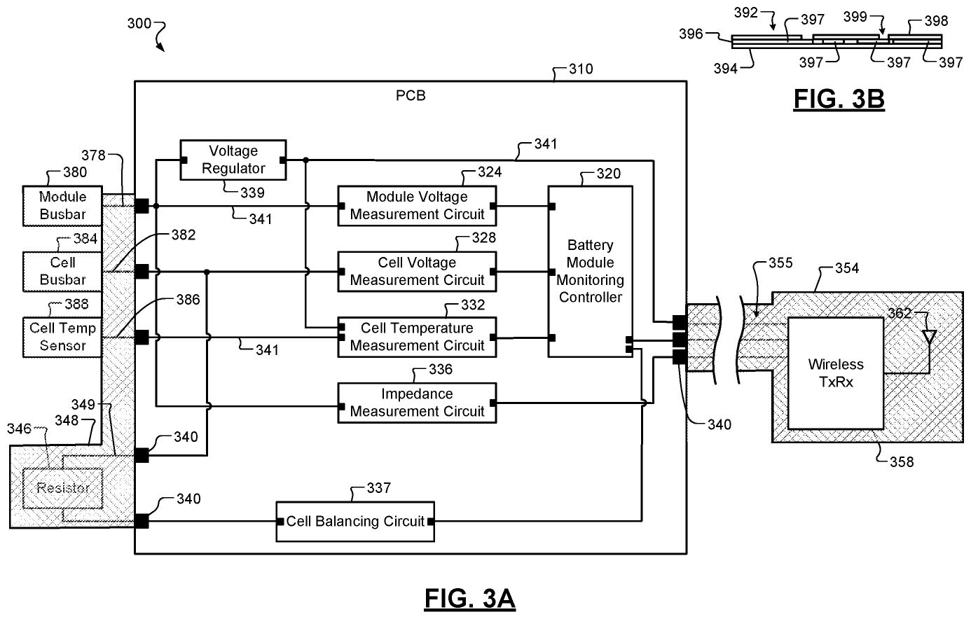

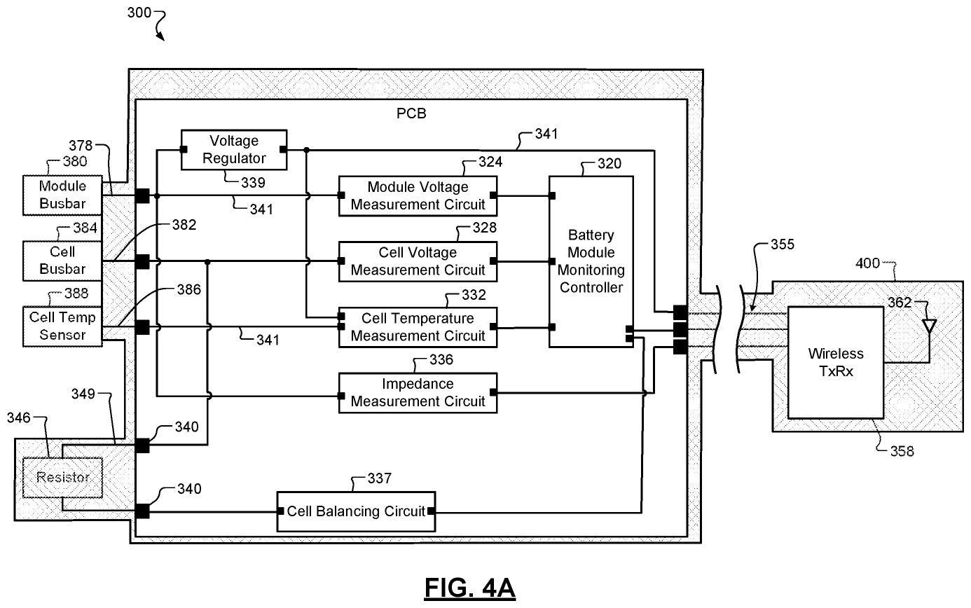

Referring now to FIGS. 3A and 3B, a battery module monitoring circuit 300 includes a PCB 310, a battery module monitoring controller 320 (e.g., an integrated circuit or chip), and/or one or more other measuring circuits such as a module voltage measuring circuit 324, a cell voltage measuring circuit 328 configured to monitor the voltages of the battery cells in the module, a cell temperature circuit 332, an impedance measuring circuit 336, a voltage regulator circuit 339, and/or a cell balancing circuit 337 on the PCB 310. The cell balancing circuit 337 selectively dissipates power from the battery cells to the resistor 346 to balance voltages of the battery cells.

A wireless transceiver 358 is mounted on a first FPC 354. An antenna 362 is mounted on the first FPC 354 or defined by a conductive layer of the first FPC 354. The conductive layer of the first FPC 354 includes one or more traces 355 connecting the wireless transceiver 358 to the battery module monitoring controller 320 and/or to the other circuits on the PCB 310.

In some examples, a resistor 346 is mounted on a second FPC 348 or defined by a conductive layer of the first FPC 354. In other examples, the resistor 346 is mounted on the PCB 310. The conductive layer of the second FPC 348 includes traces 349 providing a connection between the resistor 346 and one or more pads 340 of the PCB 310. In some examples, the conductive layer of the second FPC 348 includes traces 378 that provide a connection between a module busbar 380 and one or more pads 340 of the PCB 310. Traces 382 provide a connection between cell busbars 384 and one or more pads 340 of the PCB 310. Traces 386 provide a connection between cell temperature sensor 388 and one or more pads 340 of the PCB 310. The pads 340 of the PCB 310 are connected by traces 341 on the PCB 310 to circuits located on the PCB or other pads.

In some examples, the battery module monitoring controller 320 communicates with the module voltage measuring circuit 324, the cell voltage measuring circuit 328, the cell temperature circuit 332, the impedance measuring circuit 336, and the cell balancing circuit 337. In some examples, the battery module monitoring controller 320 communicates with the wireless transceiver 358. In some examples, the module voltage measuring circuit 324 communicates with the module busbar 380. The cell voltage measuring circuit 328 communicates with the cell busbars 384. The cell temperature circuit 332 communicates with the cell temperature sensor 388 and the voltage regulator circuit 339. The impedance measuring circuit 336 communicates with the voltage regulator circuit 339 and the wireless transceiver 358. The cell balancing circuit 337 communicates with the resistor 346.

Referring now to FIG. 3B, an example of a FPC 392 is shown. The FPC includes a first insulating layer 394, a conducting layer 396, and a second insulating layer 398 (optional). In some examples, the conducting layer 396 is arranged between the first insulating layer 394 and the second insulating layer 398. In some examples, the conducting layer 396 is made of a layer of conducting metal such as aluminum (AI), copper (Cu) or other suitable conducting materials. In some examples, the insulating layers include film such as polyethylene terephthalate (PET), polyethylene naphthalate (PEN), polyimide (PI), or other suitable insulating materials. The conducting layer is patterned into traces 397. Openings 399 may be made in one or both of the insulating layers.

In some examples, portions of the conducting layer 396 of the FPC 392 are patterned using a dry milling process. A suitable example of a dry milling process is shown and described in U.S. Pat. No. 7,919,027, issued on Apr. 5, 2011 and entitled “Methods and Devices for Manufacturing of Electrical Components and Laminated Structures”, which is hereby incorporated herein by reference in its entirety. During dry milling, a web is fed between a milling wheel and a cliché.

The cliché includes a rotating drum and a flexible substrate with a pattern including raised portions and non-raised portions. The substrate is attached to the drum. In some examples, the pattern is made using photolithography. The milling wheel is arranged on an opposite side of the web. The raised portions of the pattern on the cliche push the conductive layer into the milling wheel and the corresponding portions of the conductive layer are removed. A similar approach can be used to mill the insulating layer. The conductive layer that remains is thereby patterned to provide traces, pads for fingers, etc. and intervening areas where the conductive layer is absent. After milling the conductive layer, another insulating layer can be arranged over the conductive layer.

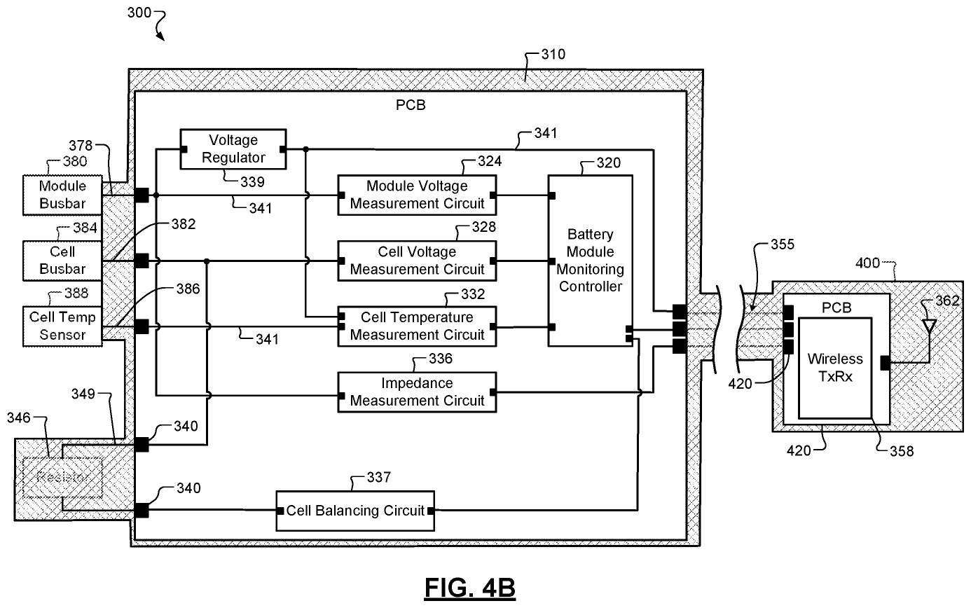

Referring now to FIGS. 4A and 4B, other mounting and packaging examples are shown. In FIG. 4A, the PCB 310 can be mounted on a FPC 400. The conductive layer of the FPC 400 includes the traces 355, 378, 382, 386, and/or 349 as described above. The wireless transceiver 358 is attached to the FPC 400. In FIG. 4B, the wireless transceiver 358 is mounted on a PCB 420 that is attached on the FPC 400. As can be appreciated, the antenna can be mounted on the PCB or form part of the PCB (e.g., implemented by traces on the PCB).

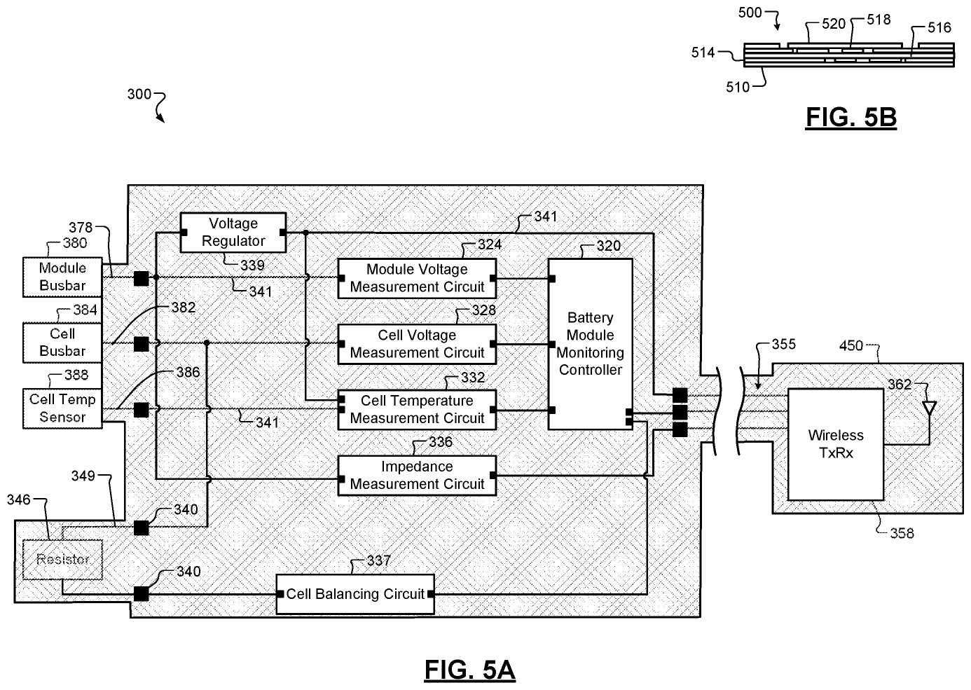

Referring now to FIGS. 5A and 5B, other mounting and packaging examples are shown. In this example, the battery module monitoring controller 320 and the one or more other circuits (e.g., the module voltage measuring circuit 324, the cell voltage measuring circuit 328, the cell temperature circuit 332, the impedance measuring circuit 336, and/or the cell balancing circuit 337) are directly mounted to a FPC 450. In some examples, one or more of the module voltage measuring circuit 324, the cell voltage measuring circuit 328, the cell temperature circuit 332, and the impedance measuring circuit 336 can be implemented by an integrated circuit or integrated with another integrated circuit. Traces 460 between the battery module monitoring controller 320 and the one or more other circuits and the traces 349, 355, 378, 382, and/or 386 described above are defined by one or more conducting layers of the FPC 450.

In some examples, the battery module monitoring controller 320 and the one or more other circuits (e.g., the module voltage measuring circuit 324, the cell voltage measuring circuit 328, the cell temperature circuit 332, the impedance measuring circuit 336, and/or the cell balancing circuit 337) are arranged such that the FPC 450 includes a single conductive layer.

In other examples shown in FIG. 5B, a FPC 500 is used and includes multiple conductive layers arranged between insulating layers so that connections can pass over one another. The FPC 500 includes a stack including first insulating layer 510, a first conducting layer 514, a second insulating layer 516, a second conducting layer 518 and a third insulating layer 520 that are patterned to provide interconnections between the battery module monitoring controller 320, the one or more other circuits (e.g., the module voltage measuring circuit 324, the cell voltage measuring circuit 328, the cell temperature circuit 332, the impedance measuring circuit 336, and cell balancing circuit 337), the wireless transceiver 358, the resistor 346, the module busbar 380, the cell busbars 384, and/or the cell temperature sensor 388. For example, the conductive layers in the stack of the FPC 500 can be milled from opposite sides and/or made using two FPCs that are milled separately and attached together with an intervening insulating layer.

Referring now to FIG. 6, a battery module monitoring circuit 620 (e.g., an integrated circuit) and/or other circuits 621 are arranged on a PCB 624 that is attached to a FPC 614 (or directly soldered to the FPC 614). The FPC 614 attached to a frame 610 located above or adjacent to the battery cells of the module.

A wireless transceiver 626 (e.g., an integrated circuit) is mounted directly to the FPC 614 (or to a PCB that is attached to the FPC 614) at a location spaced from the PCB 624. In some examples, connections between the wireless transceiver 626 and the battery module monitoring circuit 620 can be implemented using traces arranged on a PCB. An antenna 628 is implemented by a conducting layer of the FPC 614 or is a separate component that is attached to the FPC 614 and connected to the wireless transceiver 626 by traces of the FPC 614. In other examples, the antenna 628 can be mounted on a PCB or form part of a PCB.

The FPC 614 also provides connections at 634 to terminals 630 that are configured to connect to the battery cells. One or more fasteners 640 may be used to attach the FPC 614 to the frame 610. The battery module monitoring circuit 620, the wireless transceiver 626, the antenna 628, the FPC 614, the frame 610, and a plurality of battery cells (not shown) are arranged in an enclosure 650 of the battery module.

The foregoing description is merely illustrative in nature and is in no way intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims. It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In the figures, the direction of an arrow, as indicated by the arrowhead, generally demonstrates the flow of information (such as data or instructions) that is of interest to the illustration. For example, when element A and element B exchange a variety of information but information transmitted from element A to element B is relevant to the illustration, the arrow may point from element A to element B. This unidirectional arrow does not imply that no other information is transmitted from element B to element A. Further, for information sent from element A to element B, element B may send requests for, or receipt acknowledgements of, the information to element A.

What is claimed is:

1. A wireless battery module monitoring system, comprising:
a flexible printed circuit (FPC) including:
a first insulating layer; and
a conductive layer defining a plurality of traces arranged in a first predetermined pattern;
a battery module monitoring circuit connected to at least one of the plurality of traces of the FPC;
a wireless transceiver connected to at least one of the plurality of traces of the FPC at a location remote from the battery module monitoring circuit; and
an antenna connected to the wireless transceiver.

2. The wireless battery module monitoring system of claim 1, wherein the antenna is one of:
mounted on the FPC and connected to the wireless transceiver; and
implemented by at least one of the plurality traces of the conductive layer of the FPC and connected to the wireless transceiver.

3. The wireless battery module monitoring system of claim 1, wherein the plurality of traces of the FPC are milled.

4. The wireless battery module monitoring system of claim 1, wherein:
the FPC includes a second insulating layer, and
the conductive layer is arranged between the first insulating layer and the second insulating layer.

5. The wireless battery module monitoring system of claim 1, further comprising a measuring circuit arranged on the FPC, connected to at least one of the plurality of traces and to the battery module monitoring circuit, and configured to measure at least one of module voltage, cell voltage, cell temperature and impedance.

6. The wireless battery module monitoring system of claim 1, wherein at least one of the plurality of traces of the conducting layer is connected at least one of a module busbar, a cell busbar, and a cell temperature sensor.

7. A battery module comprising:
a battery enclosure including a plurality of battery cells;
a frame; and
the wireless battery module monitoring system of claim 1 arranged on the frame in the battery enclosure.

8. A wireless battery module monitoring system, comprising:
a first printed circuit board (PCB);
a battery module monitoring circuit arranged on the first PCB;
a first flexible printed circuit (FPC) including a first insulating layer and a first conductive layer defining a plurality of first traces arranged in a first predetermined pattern,
a wireless transceiver arranged on the first FPC at a location remote from the first PCB, and connected to at least one of the plurality of first traces; and
an antenna connected to the wireless transceiver.

9. The wireless battery module monitoring system of claim 8, wherein the antenna is one of:
mounted on the first FPC and connected to the wireless transceiver; and
implemented by at least one of the plurality of first traces and connected to the wireless transceiver.

10. The wireless battery module monitoring system of claim 8, wherein the plurality of first traces of the first FPC are milled.

11. The wireless battery module monitoring system of claim 8, wherein the first FPC further comprises a second insulating layer, wherein the first conducting layer is arranged between the first insulating layer and the second insulating layer.

12. The wireless battery module monitoring system of claim 8, wherein the first PCB is arranged adjacent to an edge of the first FPC and at least one of the plurality of first traces is connected to at least one pad on the first PCB.

13. The wireless battery module monitoring system of claim 8, wherein the first PCB is mounted above the first FPC and is soldered to at least one of the plurality of first traces.

14. The wireless battery module monitoring system of claim 13, further comprising a measuring circuit arranged on the first PCB, connected by at least one of the plurality of traces of the first FPC to the battery module monitoring circuit, and configured to measure at least one of module voltage, cell voltage, cell temperature and impedance.

15. The wireless battery module monitoring system of claim 8, further comprising:
a second FPC including a second insulating layer and second conducting layer defining a plurality of second traces arranged in a second predetermined pattern,
wherein at least one of the plurality of second traces defines a resistor connected to at least one pad of the first PCB.

16. The wireless battery module monitoring system of claim 15, wherein at least one of the plurality of second traces of the second conducting layer connects at least one of a module busbar, a cell busbar, and a cell temperature sensor to one or more pads of the first PCB.

17. The wireless battery module monitoring system of claim 15, wherein the plurality of second traces of the second FPC are milled.

18. The wireless battery module monitoring system of claim 8, wherein the wireless transceiver is mounted on a second PCB attached to the first FPC.

19. A battery module comprising:
a plurality of battery cells;
a frame;
a battery enclosure; and
the wireless battery module monitoring system of claim 8 arranged on the frame in the battery enclosure.
